(19) United States
(12) Patent Application Publication
(10) Pub. No.: US 2007/0044831 A1
(43) Pub. Date: Mar. 1, 2007

(54) Electrolyte composition and dye-sensitized solar cell

(75) Inventors: Shuzi Hayase, Kitakyushu-Shi (JP); Shinichi Kadono, Fukuyam a-shi (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignees: NATIONAL UNIVERSITY CORPORATION KYUSHU INSTITUTE OF TECHNOLOGY, Kitakyushu-shi (JP); MANAC INC., Fukuyama-shi (JP)

(21) Appl. No.: 11/372,350

(22) Filed: Mar. 10, 2006

(30) Foreign Application Priority Data
Aug. 31, 2005 (JP) 2005-251348

(51) Int. Cl. H01L 31/00; H01M 10/40

(52) U.S. Cl. 136/252; 429/304

(57) ABSTRACT

The present invention provides an electrolyte composition that can simultaneously realize solidification of the electrolyte layer and alleviation of a reduction in photoelectric conversion rate caused by the solidification of electrolyte layers, and a dye-sensitized solar cell having a solid electrolyte layer comprising the electrolyte composition. The electrolyte composition includes nanoparticles with an ammonium group or a nitrogen-containing heterocyclic group bound thereto; or a porous inorganic film with an ammonium group or a nitrogen-containing heterocyclic group bound thereto. The nanoparticles and the porous inorganic film each are formed of a metal oxide. The nitrogen-containing heterocyclic group is an imidazolium group, a pyridinium group, a triazolium group or a guanidinium group, and the counter anion group is F⁻, Cl⁻, Br⁻, I⁻ or the like. The ammonium group or the nitrogen-containing heterocyclic group chemically modifies the nanoparticles or the porous inorganic film. The electrolyte layer of the dye-sensitized solar cell includes the electrolyte composition.

### BACKGROUND OF THE INVENTION

1. Field of the Invention

The present invention relates to an electrolyte composition and a dye-sensitized solar cell using for the solid electrolyte layer thereof the electrolyte composition.

2. Description of the Related Art

Dye-sensitized solar cells usually contain in the electrolyte layer thereof a liquid electrolyte including a low molecular weight solvent, and accordingly, a problem is raised in that the photoelectric conversion rate is degraded due to the liquid leakage and the solvent evaporation.

For the purpose of solving the above described problem, solidification (gelation) of the electrolyte layer has been studied.

As a method for solidifying the electrolyte layer, there has been proposed a method in which nanoparticles are added to an electrolytic solution (electrolyte solution) (for example, see Non-patent Document 1).

However, although the solidification becomes remarkable with the addition of a nanoparticles, there is such a problem that the photoelectric current or the photoelectric conversion rate is significantly reduced with the addition of nanoparticles.

Alternatively, for the purpose of improving the photoelectric conversion rate, there has been proposed a method in which an electrolyte composition containing an imidalzolium salt is used for the electrolyte solution (for example, see Patent Document 1).

Needless to say, this method cannot attain the solidification of the electrolyte layer.

In a contrast to these method, there has been proposed a method in which an electrolyte composition containing nanoparticles and an imidazolium cation is used for the electrolyte layer for the purpose of simultaneously realizing the solidification of the electrolyte layer and the prevention of degradation of the photoelectric conversion rate caused by the solidification of electrolyte layers (for example, see Non-patent Document 2). In this case, the situation involved is such that the imidazolium cations are adsorbed on the surface of the nanoparticles.

[Patent Document 1]: Japanese Patent Laid-Open No. 2001-160427.

[Non-patent Document 1]: J. H. Kim, M-S. Kang, Y. J. Kim, J. Won, N-G. Park and Y. S, Kang, Chem. Comm., 2004, 1662.

[Non-patent Document 2]: H. Usui, H. Matsui, N. Tanabe and S. Yanagida, J. Photochem. Photobiol., A: Chem., 164(2004), 97.

### SUMMARY OF THE INVENTION

However, a dye-sensitized solar cell having an electrolyte layer comprising an electrolyte composition in the form of the above described nanoparticles having imidazolium cations adsorbed on the surface thereof cannot sufficiently overcome a significant reduction in photoelectric conversion rate caused by the solidification of electrolyte layers.

The present invention has been achieved in view of the above described problem, and an object of the present invention is to provide an electrolyte composition that can simultaneously realize solidification of the electrolyte layer and alleviation of a reduction in photoelectric conversion rate caused by the solidification of electrolyte layers, and a dye-sensitized solar cell having a solid electrolyte layer comprising the electrolyte composition.

The electrolyte composition according to the present invention is characterized in that the electrolyte composition includes nanoparticles with an ammonium group or a nitrogen-containing heterocyclic group bound thereto, or a porous inorganic film with an ammonium group or a nitrogen-containing heterocyclic group bound thereto.

The electrolyte composition according to the present invention is also characterized in that the nanoparticles and the porous inorganic film each are formed of a metal oxide.

Further, the electrolyte composition according to the present invention is characterized in that: the nitrogen-containing heterocyclic group includes one or more groups selected from the group consisting of an imidazolium group represented by the following general formula (1), a pyridinium group represented by the following general formula (2), a triazolium group represented by the following general formula (3), and a guanidinium group represented by the following general formula (4); and the counter anion group is selected from the group consisting of F⁻, Cl⁻, Br⁻, I⁻ and a compound represented by the following general formula (5) 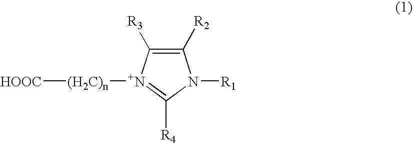
wherein R₁ to R₄ each are a hydrogen atom or an alkyl group having 1 to 10 carbon atoms, and may be the same or different from each other; and n is an integer of 4 to 20; 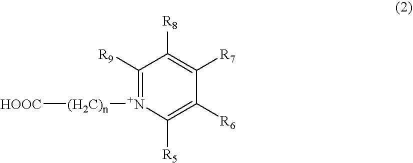
wherein R₅ to R₉ each are a hydrogen atom or an alkyl group having 1 to 10 carbon atoms, and may be the same or different from each other; and n is an integer of 4 to 20; 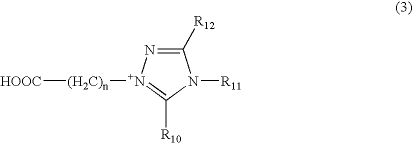
wherein R₁₀ to R₁₂ each are a hydrogen atom or an alkyl group having 1 to 10 carbon atoms, and may be the same or different from each other; and n is an integer of 4 to 20; 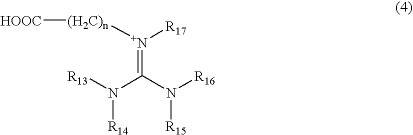
wherein R₁₃ to R₁₇ each are a hydrogen atom or a phenyl group, and may be the same or different from each other; and n is an integer of 4 to 20;
Y—(CH₂)ₙ—COOH (5)
wherein Y represents —SO₃⁻ or —COO⁻, and n is an integer of 4 to 20.

Further, the electrolyte composition according to the present invention is characterized in that the ammonium group is a compound represented by the following general formula (6), and the counter anion group is F⁻, Cl⁻, Br⁻ or I⁻: 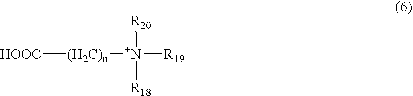
wherein R₁₈ to R₂₀ each are a hydrogen atom or an alkyl group having 1 to 10 carbon atoms, and may be the same or different from each other; and n is an integer of 4 to 20.

Further, the electrolyte composition according to the present invention is characterized in that the electrolyte composition is formed of the nanoparticles or the porous inorganic film chemically modified by the ammonium group or the nitrogen-containing heterocyclic group through the intermediary of an acyclic hydrocarbon group straight chain having a functional group at one end thereof.

Furthermore, the dye-sensitized solar cell according to the present invention is a dye-sensitized solar cell which includes a semiconductor electrode with a dye adsorbed on the surface thereof, a counter electrode disposed so as to face the semiconductor electrode, and an electrolyte layer disposed between the semiconductor electrode and the counter electrode, characterized in that the electrolyte layer includes the above described electrolyte composition.

The electrolyte composition according to the present invention includes nanoparticles with an ammonium group or a nitrogen-containing heterocyclic group bound thereto or a porous inorganic film with an ammonium group or a nitrogen-containing heterocyclic group bound thereto. Herewith, a dye-sensitized solar cell having an electrolyte layer comprising this electrolyte composition can simultaneously realize solidification of the electrolyte layer and alleviation of a reduction in photoelectric conversion rate caused by the solidification of electrolyte layers.

### BRIEF DESCRIPTION OF THE DRAWINGS

FIG. 1 is a schematic sectional view of a dye-sensitized solar cell of the present invention; and

FIG. 2 is a schematic view illustrating a chemically modified nanoparticle constituting an electrolyte layer of the present invention.

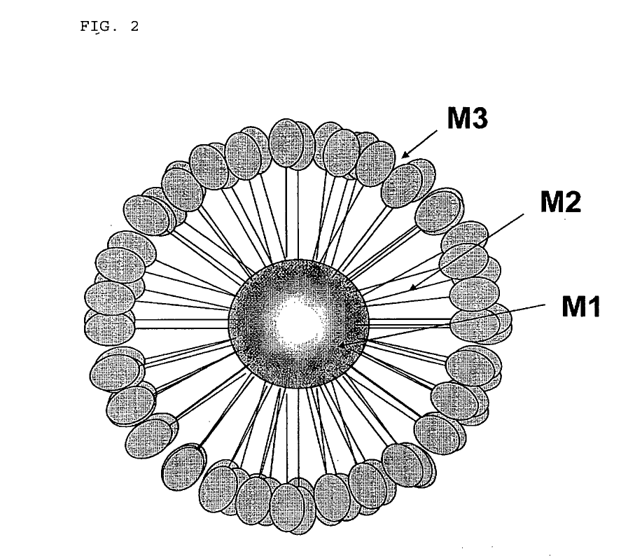

### DETAILED DESCRIPTION OF THE PREFERRED EMBODIMENTS

Hereinbelow, embodiments of the present invention are described.

First, the electrolyte composition of the present invention is described.

The electrolyte composition of the present invention includes nanoparticles with an ammonium group or a nitrogen-containing heterocyclic group bound thereto or a porous inorganic film with an ammonium group or a nitrogen-containing heterocyclic group bound thereto.

The nanoparticles and the porous inorganic film are not particularly constrained with respect to material type as long as they can realize solidification of the electrolyte layer, but each are preferably formed of a metal oxide. The metal element of the metal oxide emcompasses Si. Examples of the metal oxide may include TiO₂, Al₂O₃, ZnO, ZrO₂ and SiO₂.

The particle size (diameter) of the nanoparticles is not particularly limited from the viewpoint of solidification of the electrolyte layer, but it is preferably 5 to 100 nm from the viewpoint that a sufficient quantity of a modifier such as an ammonium group or the like should be bound to the surface of the nanoparticles and the like.

The nitrogen-containing heterocyclic group is not particularly limited for type from the viewpoint of improving the electric conductivity of the electrolyte layer. However, the nitrogen-containing heterocyclic group is preferably one or more groups selected from the group consisting of an imidazolium group represented by the following general formula (1), a pyridinium group represented by the following general formula (2), a triazolium group represented by the following general formula (3), and a guanidinium group represented by the following general formula (4); and the counter anion group is selected from the group consisting of F⁻, Cl⁻, Br⁻, I⁻ and a compound represented by the following general formula (5) 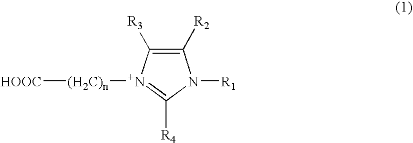
wherein R₁ to R₄ each are a hydrogen atom or an alkyl group having 1 to 10 carbon atoms, and may be the same or different from each other; and n is an integer of 4 to 20; 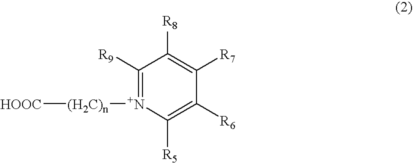
wherein R₅ to R₉ each are a hydrogen atom or an alkyl group having 1 to 10 carbon atoms, and may be the same or different from each other; and n is an integer of 4 to 20; 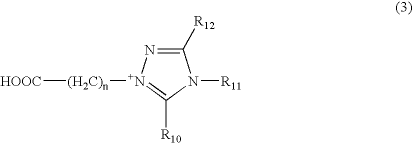
wherein R₁₀ to R₁₂ each are a hydrogen atom or an alkyl group having 1 to 10 carbon atoms, and may be the same or different from each other; and n is an integer of 4 to 20; 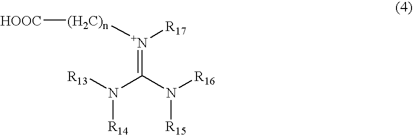
wherein R₁₃ to R₁₇ each are a hydrogen atom or a phenyl group, and may be the same or different from each other; and n is an integer of 4 to 20; and
Y—(CH₂)ₙ—COOH (5)
wherein Y represents —SO₃⁻ or —COO⁻, and n is an integer of 4 to 20.

The ammonium group is also not particularly limited for type from the viewpoint of improving the electric conductivity of the electrolyte layer; however, the ammonium group is preferably a compound represented by the following general formula (6), and the counter anion group is F⁻, Cl⁻, Br⁻ or I⁻: 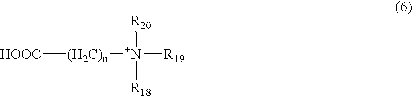
wherein R₁₈ to R₂₀ each are a hydrogen atom or an alkyl group having 1 to 10 carbon atoms, and may be the same or different from each other; and n is an integer of 4 to 20.

Examples of the imidazolium group represented by the above described general formula (1) may include the following compounds:
Carboxybutylmethylimidazolium
Carboxypentylmethylimidazolium
Carboxyhexylmethylimidazolium
Carboxyheptylmethylimidazolium
Carboxyoctylmethylimidazolium
Carboxynonylmethylimidazolium
Carboxydecanylmethylimidazolium
Carboxyindecanylmethylimidazolium
Carboxydodecanylmethylimidazolium
Carboxytridecanylmethylimidazolium
Carboxytetradecanylmethylimidazolium
Carboxypentadecanylmethylimidazolium
Carboxyhexadecanylmethylimidazolium
Carboxyheptadecanylmethylimidazolium
Carboxyoctadecanylmethylimidazolium
Carboxynonadecanylmethylimidazolium
Carboxyicosanylmethylimidazolium
Carboxybutylimidazolium
Carboxypentylimidazolium
Carboxyhexylimidazolium
Carboxyheptylimidazolium
Carboxyoctylimidazolium
Carboxynonylimidazolium
Carboxydecanylimidazolium
Carboxyindecanylimidazolium
Carboxydodecanylimidazolium
Carboxytridecanylimidazolium
Carboxytetradecanylimidazolium
Carboxypentadecanylimidazolium
Carboxyhexadecanylimidazolium
Carboxyheptadecanylimidazolium
Carboxyoctadecanylimidazolium
Carboxynonadecanylimidazolium
Carboxyicosanylimidazolium
Carboxybutyldimethylimidazolium
Carboxypentyldimethylimidazolium
Carboxyhexyldimethylimidazolium
Carboxyheptyldimethylimidazolium
Carboxyoctyldimethylimidazolium
Carboxynonyldimethylimidazolium
Carboxydecanyldimethylimidazolium
Carboxyindecanyldimethylimidazolium
Carboxydodecanyldimethylimidazolium
Carboxytridecanyldimethylimidazolium
Carboxytetradecanyldimethylimidazolium
Carboxypentadecanyldimethylimidazolium
Carboxyhexadecanyldimethylimidazolium
Carboxyheptadecanyldimethylimidazolium
Carboxyoctadecanyldimethylimidazolium
Carboxynonadecanyldimethylimidazolium
Carboxyicosanyldimethylimidazolium
Carboxybutylmethylphenylimidazolium
Carboxypentylmethylphenylimidazolium
Carboxyhexylmethylphenylimidazolium
Carboxyheptylmethylphenylimidazolium
Carboxyoctylmethylphenylimidazolium
Carboxynonylmethylphenylimidazolium
Carboxydecanylmethylphenylimidazolium
Carboxyindecanylmethylphenylimidazolium
Carboxydodecanylmethylphenylimidazolium
Carboxytridecanylmethylphenylimidazolium
Carboxytetradecanylmethylphenylimidazolium
Carboxypentadecanylmethylphenylimidazolium
Carboxyhexadecanylmethylphenylimidazolium
Carboxyheptadecanylmethylphenylimidazolium
Carboxyoctadecanylmethylphenylimidazolium
Carboxynonadecanylmethylphenylimidazolium
Carboxyicosanylmethylphenylimidazolium

Examples of the pyridinium group represented by the above described general formula (2) may include the following compounds:
Carboxybutylmethylpyridinium
Carboxypentylmethylpyridinium
Carboxyhexylmethylpyridinium
Carboxyheptylmethylpyridinium
Carboxyoctylmethylpyridinium
Carboxynonylmethylpyridinium
Carboxydecanylmethylpyridinium
Carboxyindecanylmethylpyridinium
Carboxydodecanylmethylpyridinium
Carboxytridecanylmethylpyridinium
Carboxytetradecanylmethylpyridinium
Carboxypentadecanylmethylpyridinium
Carboxyhexadecanylmethylpyridinium
Carboxyheptadecanylmethylpyridinium
Carboxyoctadecanylmethylpyridinium
Carboxynonadecanylmethylpyridinium
Carboxyicosanylmethylpyridinium
Carboxybutylpyridinium
Carboxypentylpyridinium
Carboxyhexylpyridinium
Carboxyheptylpyridinium
Carboxyoctylpyridinium
Carboxynonylpyridinium
Carboxydecanylpyridinium
Carboxyindecanylpyridinium
Carboxydodecanylpyridinium
Carboxytridecanylpyridinium
Carboxytetradecanylpyridinium
Carboxypentadecanylpyridinium
Carboxyhexadecanylpyridinium
Carboxyheptadecanylpyridinium
Carboxyoctadecanylpyridinium
Carboxynonadecanylpyridinium
Carboxyicosanylpyridinium
Carboxybutyldimethylpyridinium
Carboxypentyldimethylpyridinium
Carboxyhexyldimethylpyridinium
Carboxyheptyldimethylpyridinium
Carboxyoctyldimethylpyridinium
Carboxynonyldimethylpyridinium
Carboxydecanyldimethylpyridinium
Carboxyindecanyldimethylpyridinium
Carboxydodecanyldimethylpyridinium
Carboxytridecanyldimethylpyridinium
Carboxytetradecanyldimethylpyridinium
Carboxypentadecanyldimethylpyridinium
Carboxyhexadecanyldimethylpyridinium
Carboxyheptadecanyldimethylpyridinium
Carboxyoctadecanyldimethylpyridinium
Carboxynonadecanyldimethylpyridinium
Carboxyicosanyldimethylpyridinium
Carboxybutylmethylphenylpyridinium
Carboxypentylmethylphenylpyridinium
Carboxyhexylmethylphenylpyridinium
Carboxyheptylmethylphenylpyridinium
Carboxyoctylmethylphenylpyridinium
Carboxynonylmethylphenylpyridinium
Carboxydecanylmethylphenylpyridinium
Carboxyindecanylmethylphenylpyridinium
Carboxydodecanylmethylphenylpyridinium
Carboxytridecanylmethylphenylpyridinium
Carboxytetradecanylmethylphenylpyridinium
Carboxypentadecanylmethylphenylpyridinium
Carboxyhexadecanylmethylphenylpyridinium
Carboxyheptadecanylmethylphenylpyridinium
Carboxyoctadecanylmethylphenylpyridinium
Carboxynonadecanylmethylphenylpyridinium
Carboxyicosanylmethylphenylpyridinium

Examples of the triazolium group represented by the above described general formula (3) may include the following compounds:
Carboxybutylmethyltriazolium
Carboxypentylmethyltriazolium
Carboxyhexylmethyltriazolium
Carboxyheptylmethyltriazolium
Carboxyoctylmethyltriazolium
Carboxynonylmethyltriazolium
Carboxydecanylmethyltriazolium
Carboxyindecanylmethyltriazolium
Carboxydodecanylmethyltriazolium
Carboxytridecanylmethyltriazolium
Carboxytetradecanylmethyltriazolium
Carboxypentadecanylmethyltriazolium
Carboxyhexadecanylmethyltriazolium
Carboxyheptadecanylmethyltriazolium
Carboxyoctadecanylmethyltriazolium
Carboxynonadecanylmethyltriazolium
Carboxyicosanylmethyltriazolium
Carboxybutyltriazolium
Carboxypentyltriazolium
Carboxyhexyltriazolium
Carboxyheptyltriazolium
Carboxyoctyltriazolium
Carboxynonyltriazolium
Carboxydecanyltriazolium
Carboxyindecanyltriazolium
Carboxydodecanyltriazolium
Carboxytridecanyltriazolium
Carboxytetradecanyltriazolium
Carboxypentadecanyltriazolium
Carboxyhexadecanyltriazolium
Carboxyheptadecanyltriazolium
Carboxyoctadecanyltriazolium
Carboxynonadecanyltriazolium
Carboxyicosanyltriazolium
Carboxybutyldimethyltriazolium
Carboxypentyldimethyltriazolium
Carboxyhexyldimethyltriazolium
Carboxyheptyldimethyltriazolium
Carboxyoctyldimethyltriazolium
Carboxynonyldimethyltriazolium
Carboxydecanyldimethyltriazolium
Carboxyindecanyldimethyltriazolium
Carboxydodecanyldimethyltriazolium
Carboxytridecanyldimethyltriazolium
Carboxytetradecanyldimethyltriazolium
Carboxypentadecanyldimethyltriazolium
Carboxyhexadecanyldimethyltriazolium
Carboxyheptadecanyldimethyltriazolium
Carboxyoctadecanyldimethyltriazolium
Carboxynonadecanyldimethyltriazolium
Carboxyicosanyldimethyltriazolium
Carboxybutylmethylphenyltriazolium
Carboxypentylmethylphenyltriazolium
Carboxyhexylmethylphenyltriazolium
Carboxyheptylmethylphenyltriazolium
Carboxyoctylmethylphenyltriazolium
Carboxynonylmethylphenyltriazolium
Carboxydecanylmethylphenyltriazolium
Carboxyindecanylmethylphenyltriazolium
Carboxydodecanylmethylphenyltriazolium
Carboxytridecanylmethylphenyltriazolium
Carboxytetradecanylmethylphenyltriazolium
Carboxypentadecanylmethylphenyltriazolium
Carboxyhexadecanylmethylphenyltriazolium
Carboxyheptadecanylmethylphenyltriazolium
Carboxyoctadecanylmethylphenyltriazolium
Carboxynonadecanylmethylphenyltriazolium
Carboxyicosanylmethylphenyltriazolium

Examples of the guanidinium group represented by the above described general formula (4) may include the following compounds:
Carboxybutylmethylguanidinium
Carboxypentylmethylguanidinium
Carboxyhexylmethylguanidinium
Carboxyheptylmethylguanidinium
Carboxyoctylmethylguanidinium
Carboxynonylmethylguanidinium
Carboxydecanylmethylguanidinium
Carboxyindecanylmethylguanidinium
Carboxydodecanylmethylguanidinium
Carboxytridecanylmethylguanidinium
Carboxytetradecanylmethylguanidinium
Carboxypentadecanylmethylguanidinium
Carboxyhexadecanylmethylguanidinium
Carboxyheptadecanylmethylguanidinium
Carboxyoctadecanylmethylguanidinium
Carboxynonadecanylmethylguanidinium
Carboxyicosanylmethylguanidinium
Carboxybutylguanidinium
Carboxypentylguanidinium
Carboxyhexylguanidinium
Carboxyheptylguanidinium
Carboxyoctylguanidinium
Carboxynonylguanidinium
Carboxydecanylguanidinium
Carboxyindecanylguanidinium
Carboxydodecanylguanidinium
Carboxytridecanylguanidinium
Carboxytetradecanylguanidinium
Carboxypentadecanylguanidinium
Carboxyhexadecanylguanidinium
Carboxyheptadecanylguanidinium
Carboxyoctadecanylguanidinium
Carboxynonadecanylguanidinium
Carboxyicosanylguanidinium
Carboxybutyldimethylguanidinium
Carboxypentyldimethylguanidinium
Carboxyhexyldimethylguanidinium
Carboxyheptyldimethylguanidinium
Carboxyoctyldimethylguanidinium
Carboxynonyldimethylguanidinium
Carboxydecanyldimethylguanidinium
Carboxyindecanyldimethylguanidinium
Carboxydodecanyldimethylguanidinium
Carboxytridecanyldimethylguanidinium
Carboxytetradecanyldimethylguanidinium
Carboxypentadecanyldimethylguanidinium
Carboxyhexadecanyldimethylguanidinium
Carboxyheptadecanyldimethylguanidinium
Carboxyoctadecanyldimethylguanidinium
Carboxynonadecanyldimethylguanidinium
Carboxyicosanyldimethylguanidinium
Carboxybutylmethylphenylguanidinium
Carboxypentylmethylphenylguanidinium
Carboxyhexylmethylphenylguanidinium
Carboxyheptylmethylphenylguanidinium
Carboxyoctylmethylphenylguanidinium
Carboxynonylmethylphenylguanidinium
Carboxydecanylmethylphenylguanidinium
Carboxyindecanylmethylphenylguanidinium
Carboxydodecanylmethylphenylguanidinium
Carboxytridecanylmethylphenylguanidinium
Carboxytetradecanylmethylphenylguanidinium
Carboxypentadecanylmethylphenylguanidinium
Carboxyhexadecanylmethylphenylguanidinium
Carboxyheptadecanylmethylphenylguanidinium
Carboxyoctadecanylmethylphenylguanidinium
Carboxynonadecanylmethylphenylguanidinium
Carboxyicosanylmethylphenylguanidinium

Examples of the ammonium group represented by the above described general formula (6) may include the following compounds:
Carboxybutyltrimethylammonium
Carboxypentyltrimethylammonium
Carboxyhexyltrimethylammonium
Carboxyheptyltrimethylammonium
Carboxyoctyltrimethylammoniummethylammonium
Carboxynonyltrimethylammonium
Carboxydecanyltrimethylammonium
Carboxyindecanyltrimethylammonium
Carboxydodecanyltrimethylammonium
Carboxytridecanyltrimethylammonium
Carboxytetradecanyltrimethylammonium
Carboxypentadecanyltrimethylammonium
Carboxyhexadecanyltrimethylammonium
Carboxyheptadecanyltrimethylammonium
Carboxyoctadecanyltrimethylammonium
Carboxynonadecanyltrimethylammonium
Carboxyicosanyltrimethylammonium
Carboxybutyltributylammonium
Carboxypentyltributylammonium
Carboxyhexyltributylammonium
Carboxyheptyltributylammonium
Carboxyoctyltributylammonium
Carboxynonyltributylammonium
Carboxydecanyltributylammonium
Carboxyindecanyltributylammonium
Carboxydodecanyltributylammonium
Carboxytridecanyltributylammonium
Carboxytetradecanyltributylammonium
Carboxypentadecanyltributylammonium
Carboxyhexadecanyltributylammonium
Carboxyheptadecanyltributylammonium
Carboxyoctadecanyltributylammonium
Carboxynonadecanyltributylammonium
Carboxyicosanyltributylammonium
Carboxybutyltriethylammonium
Carboxypentyltriethylammonium
Carboxyhexyltriethylammonium
Carboxyheptyltriethylammonium
Carboxyoctyltriethylammonium
Carboxynonyltriethylammonium
Carboxydecanyltriethylammonium
Carboxyindecanyltriethylammonium
Carboxydodecanyltriethylammonium
Carboxytridecanyltriethylammonium
Carboxytetradecanyltriethylammonium
Carboxypentadecanyltriethylammonium
Carboxyhexadecanyltriethylammonium
Carboxyheptadecanyltriethylammonium
Carboxyoctadecanyltriethylammonium
Carboxynonadecanyltriethylammonium
Carboxyicosanyltriethylammonium
Carboxybutyltrihexylammonium
Carboxypentyltrihexylammonium
Carboxyhexyltrihexylammonium
Carboxyheptyltrihexylammonium
Carboxyoctyltrihexylammonium
Carboxynonyltrihexylammonium
Carboxydecanyltrihexylammonium
Carboxyindecanyltrihexylammonium
Carboxydodecanyltrihexylammonium
Carboxytridecanyltrihexylammonium
Carboxytetradecanyltrihexylammonium
Carboxypentadecanyltrihexylammonium
Carboxyhexadecanyltrihexylammonium
Carboxyheptadecanyltrihexylammonium
Carboxyoctadecanyltrihexylammonium
Carboxynonadecanyltrihexylammonium
Carboxyicosanyltrihexylammonium

The respective groups and the nanoparticles or porous inorganic film may be directly bound to each other, or may be indirectly bound to each other in such a manner that the ammonium group or the nitrogen-containing heterocyclic group chemically modifies the nanoparticles or the porous inorganic film through the intermediary of an acyclic hydrocarbon group straight chain having a functional group at one end thereof.

The electrolyte composition of the present invention contains, for example, an appropriate amount of an electrolytic solution containing, as a redox substance in addition to the above described components, a component composed of a combination of iodide ion and iodine. Specifically, there may be used combinations of metal iodides such as LiI, NaI and CaI₂ and iodine. Alternatively, examples of the other combinations may include bromide ion-bromine, thallium ion (III)-thallium ion (I), mercury ion (II)-mercury ion (I) and the like. Here, containing an appropriate amount of an electrolytic solution means that the electrolyte composition includes an electrolyte in such a range that the electrolyte composition maintains solidification (gelation) condition and the efficiency of the solar cell is not drastically decreased.

The electrolyte composition of the present invention that is composed as described above remains solid (gel).

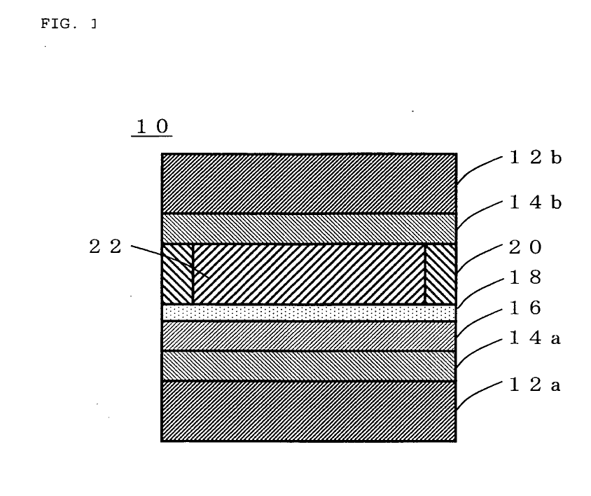

Next, FIG. 1 shows an example of the configuration of the dye-sensitized solar cell (hereinafter, also referred to simply as a cell) of the present invention that has an electrolyte layer comprising the electrolyte composition of the present invention.

FIG. 1 is a schematic sectional view of the cell; the cell 10 includes a pair of transparent substrates 12a and 12b facing each other. The transparent substrate 12a is coated with a transparent conductive film 14a, and further with a metal oxide semiconductor layer 16. The metal oxide semiconductor layer 16 supports a sensitizing dye layer 18, to thereby form an electrode (semiconductor electrode). The transparent glass plate 12b is coated with a transparent conductive film 14b. Further, a good conductive metal is deposited by sputtering (not shown in the figure) on the transparent conductive film 14b, to thereby form another electrode (counter electrode).

A separator 20 is interposed between the two electrodes, more strictly, between the metal oxide semiconductor layer 16 and the transparent conductive film 14b, to form and define an enclosed space. Inside the enclosed space, an electrolyte layer 22 is disposed.

The components of the cell 10, other than the electrolyte layer 22, are not particularly limited for material types, but can be formed of some materials appropriately selected from common materials. The film thickness and the like can also be appropriately set.

The transparent substrates 12a and 12b each may be, for example, a glass plate or a plastic plate.

The transparent conductive films 14a and 14b each may be made of, for example, ITO, SnO₂ or the like.

For the metal oxide semiconductor layer 16, for example, titanium, tin, zirconium, zinc, indium, tungsten, iron, nickel, silver or the like may be used as the metal thereof.

For the dye of the sensitizing dye layer 18, for example, the metal dyes or non-metal dyes such as complexes of transition metals such as ruthenium, phthalocyanines, porphins or the like may be used.

Good conductive materials to be deposited by sputtering, such as platinum, conductive polymers and substances free from corrosion by iodine such as carbon may be used as well as gold.

The electrolyte layer 22 is formed between the metal oxide semiconductor layer 16 and the transparent conductive film 12b with the electrolyte composition, gelated beforehand, of the present invention by a coating method, a printing method or the like. The formation of the electrolyte layer 22 is thereby facilitated, and mass production and area enlargement of the dye-sensitized solar cell can be expected.

The dye-sensitized solar cell of the present invention is free from a reduction in photoelectric conversion rate caused by the liquid leakage and the solvent evaporation which may occur if the electrolyte layer comprises a liquid electrolyte containing a low molecular weight solvent, and can alleviate a reduction in photoelectric conversion rate which may occur in solidification of electrolyte layers.

### EXAMPLES

The present invention will be described in more detail with reference to examples and comparative examples. However, it is construed that the present invention is not limited to the examples described below.

### Example 1

On a transparent substrate (manufactured by Nippon Sheet Glass Co., Ltd.; 30 ohm/sq) on which a transparent conductive film made of SnO₂ was vacuum deposited, the D paste manufactured by Solaronix SA (trade name: Ti-Nanoxide D) was coated and baked at 450° C. for 30 minutes to prepare a 9 μm thick titania electrode (titanium dioxide semiconductor layer). Subsequently, the transparent substrate with the titania electrode formed thereon was soaked in an ethanol solution in which 0.1% by mass of cis-di(thiocyanato)-N,N′-bis(2,2′-bipyridyl-4,4′-dicarbox ylato)ruthenium(II) (manufactured by Kojima Chemicals Co., Ltd.) was dissolved.

Aside from this, a transparent substrate with a platinum-containing transparent conductive film sputtered thereon was prepared as the counter electrode.

An electrolyte composition was obtained in the following manner.

Specifically, TiO₂ nanoparticles (trade name: P25; manufactured by Japan Aerosil Co., Ltd.; particle diameter: 21 nm) were added to an acetonitrile solution in which 8-bromooctanoic acid was dissolved, and the mixture was stirred at room temperature all day in a dark room. The mixture thus obtained was filtered to obtain a solid, which was washed with acetonitrile to remove the remaining 8-bromooctanoic acid, and was further dried to obtain TiO₂ nanoparticles with 8-bromooctanoic acid bound thereto. The TiO₂ nanoparticles with 8-bromooctanoic acid bound thereto were added to an acetonitrile solution in which methylimidazole was dissolved, and the solution was stirred at room temperature for one day in a dark room. The mixture thus obtained was filtered to obtain a solid, which was washed with acetonitrile, and dried under reduced pressure (under vacuum) to obtain TiO₂ nanoparticles chemically modified with an adduct (bound molten salt molecule A) of methylimidazole (methylimidazole group) and 8-bromooctanoic acid (8-bromooctanoic acid group). To an electrolytic solution composed of methylpropylimidazolium iodide (water content: 5% by mass) containing 300 mM I₂, 500 mM LiI, and 580 mM t-butylpyridine, the modified particles were added with a ratio (particles/electrolytic solution=1) shown in Table 1 to yield a gelled electrolyte composition.

The electrolyte composition was coated on the titania electrode formed on the transparent substrate, the counter electrode was superposed through the electrolyte composition on the transparent substrate with the titania electrode formed thereon by using 50-μm Himilan (trade name; a resin manufactured by Mitsui-Dupont Chemicals Co.) as a spacer and adhesive, to fabricate a cell.

The area of the fabricated cell was 0.25 cm², and the solar cell efficiency (photoelectric conversion rate) was measured with a solar simulator (YSS-50A; manufactured by Yamashita Denso Corp.; AM1.5; 100 mW/cm²).

The conditions of preparation of the electrolyte composition and the solar cell efficiency, respectively, are shown in Table 1.

TABLE 1

| | | Example 1 | Example 2 | Example 3 | Example 4 | Example 5 | Example 6 | Comp. Ex. 1 | Comp. Ex. 2 |
|---|---|---|---|---|---|---|---|---|---|
| Particles | Type of particles | Tio2 | Tio2 | Tio2 | Tio2 | Tio2 | Tio2 | Tio2 | — |
| | Particle diameter (nm) | 21 | 21 | 21 | 21 | 21 | 21 | 21 | — |
| Bound molten | Number of C atoms in | 8 | 10 | 12 | 16 | 16 | 16 | — | — |
| salt molecule | alkyl group (n value) | | | | | | | | |
| | Type of bound molten | A | A | A | A | A | A | — | — |
| | salt molecule | | | | | | | | |
| | Type of X | 1 | 1 | 1 | 1 | Br | Ci | — | — |
| | Particles/electrolytic | 1 | 1 | 1 | 1 | 1 | 1 | — | — |
| | solution (mass ratio) | | | | | | | | |
| | Photoelectric conversion | 6 | 6.4 | 6.5 | 7 | 6.1 | 5.3 | 3.5 | 7.2 |
| | rate (AM 1.5, 100 mW/cm2) % | | | | | | | | |

### Examples 2 to 19

Cells were fabricated and their solar cell efficiencies were measured in the same manner as in Example 1 except that, in each example, the types of nanoparticles and bound molten salt molecule were changed as shown in Table 1 to 3. The conditions of preparation of the electrolyte compositions and the solar cell efficiencies, respectively, are shown in Tables 1, 2 and 3.

TABLE 2

| | | Example 7 | Example 8 | Example 9 | Example 10 | Example 11 | Example 12 | Example 13 |
|---|---|---|---|---|---|---|---|---|
| Particles | Type of particles | SiO2 | SnO2 | Al2O3 | ZnO | ZrO2 | Porous | Porous |
| | | | | | | | alumina film | titania film |
| | Particle diameter | 15 | 20 | 20 | 20 | 20 | | |
| | (nm) | | | | | | | |
| Bound molten | Number of C atoms | 16 | 16 | 16 | 16 | 16 | | |
| salt molecule | in alkyl group (n value) | | | | | | | |
| | Type of bound molten | A | A | A | A | A | A | A |
| | salt molecule | | | | | | | |
| | Type of X | 1 | 1 | 1 | 1 | Br | 1 | 1 |
| | Particles/electrolytic | 1 | 1 | 1 | 1 | 1 | — | — |
| | solution (mass ratio) | | | | | | | |
| | Photoelectric conversion | 7 | 5.5 | 5.7 | 6 | 6 | 6.5 | 6.5 |
| | rate (AM 1.5, 100 mW/cm2) % | | | | | | | |

TABLE 3

| | | Example 14 | Example 15 | Example 16 | Example 17 | Example 18 | Example 19 |
|---|---|---|---|---|---|---|---|
| Particles | Type of particles | Tio2 | Tio2 | Tio2 | Tio2 | Tio2 | Tio2 |
| | Particle diameter (nm) | 21 | 21 | 21 | 21 | 21 | 21 |
| Bound molten | Number of C atoms in | 16 | 16 | 16 | 16 | 16 | 16 |
| salt molecule | alkyl group (n value) | | | | | | |
| | Type of bound molten | A | B | C | C | D | E |
| | salt molecule | | | | | | |
| | Type of X | 1 | I | — | — | — | 1 |
| | Type of Y | — | — | SO3- | COO— | COO— | — |
| | Particles/electrolytic | 1 | 1 | 1 | 1 | 1 | 1 |
| | solution (mass ratio) | | | | | | |
| | Photoelectric conversion | 7 | 6.5 | 6.4 | 6.4 | 6.7 | 6.7 |
| | rate (AM 1.5, 100 mW/cm2) % | | | | | | |

Here, in each table, the bound molten salt molecules A to E are the compounds having the following structural formulas, respectively; A is an imidazolium group-containing compound, B is a pyridinium group-containing compound, C and E are a compound containing an ammonium group, and D is a guanidinium compound. It is to be noted that in D, Ph represents a phenyl group.

As illustrated in Table 2, the nanoparticle with bound modifier molecules thereon in each Example has such a form that the surface of the nanoparticle (M1) is covered with a large number of long chain compound (M2) molecules each having a functional group at one end thereof, and a bound molten salt molecule (M3) is bound to the other end of each long chain compound (M2) molecule.

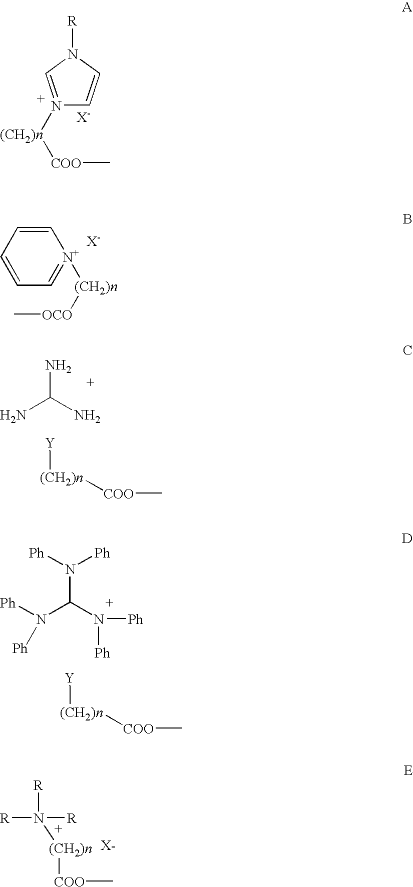

### Comparative Examples 1 and 2

As Comparative Example 1, a cell was fabricated in the same manner as in Example 1 except that an electrolyte composition containing a gelled solid containing TiO₂ as nanoparticle and methylimidazole ion as molten salt ion was used. As Comparative Example 2, a cell was fabricated in the same manner as in Example 1 except that an electrolyte composition containing only the electrolytic solution used in Examples was used. The conditions of the preparation of the electrolyte composition and the solar cell efficiency of each of Comparative Examples are shown in Table 1, respectively.

As can be seen from Tables 1 to 3, as compared to Comparative Example 1 in which no molten salt is bound to the nanoparticles, each of Examples is significantly larger in solar cell efficiency.

As also can be seen from these tables, with an increasing number of carbon atoms (the hydrocarbon chain length), the solar cell efficiency is increased.

As also can be seen from these tables, as compared to Comparative Example 2 in which only an electrolytic solution was used and thus contained neither nanoparticles nor bound molten salt molecules, Comparative Example 1 is largely decreased in solar cell efficiency, but each Example is significantly alleviated in a reduction in solar cell efficiency.

1. An electrolyte composition, comprising:
nanoparticles with an ammonium group or a nitrogen-containing heterocyclic group bound thereto; or
a porous inorganic film with an ammonium group or a nitrogen-containing heterocyclic group bound thereto.

2. The electrolyte composition according to claim 1, wherein said nanoparticles and said porous inorganic film each are formed of a metal oxide.

3. The electrolyte composition according to claim 1, wherein:
said nitrogen-containing heterocyclic group comprises one or more groups selected from the group consisting of an imidazolium group represented by the following general formula (1), a pyridinium group represented by the following general formula (2), a triazolium group represented by the following general formula (3), and a guanidinium group represented by the following general formula (4); and
a counter anion group is selected from the group consisting of F⁻, Cl⁻, Br⁻, I⁻ and a compound represented by the following general formula (5): 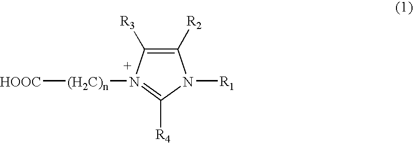
wherein R₁ to R₄ each are a hydrogen atom or an alkyl group having 1 to 10 carbon atoms, and may be the same or different from each other; and n is an integer of 4 to 20; 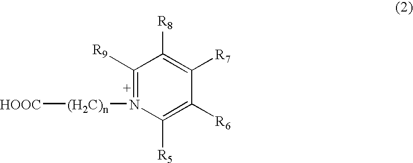
wherein R₅ to R₉ each are a hydrogen atom or an alkyl group having 1 to 10 carbon atoms, and may be the same or different from each other; and n is an integer of 4 to 20; 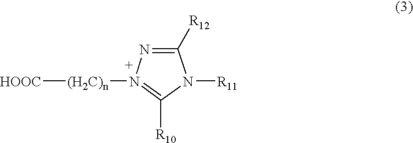
wherein R₁₀ to R₁₂ each are a hydrogen atom or an alkyl group having 1 to 10 carbon atoms, and may be the same or different from each other; and n is an integer of 4 to 20; 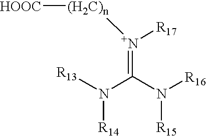
wherein R₁₃ to R₁₇ each are a hydrogen atom or a phenyl group, and may be the same or different from each other; and n is an integer of 4 to 20; and
Y—(CH₂)ₙ—COOH (5)
wherein Y represents —SO₃⁻ or —COO⁻, and n is an integer of 4 to 20.

4. The electrolyte composition according to claim 1, wherein said ammonium group is a compound represented by the following general formula (6), and a counter anion group is F⁻, Cl⁻, Br⁻ or I⁻: 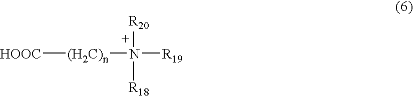
wherein R₁₈ to R₂₀ each are a hydrogen atom or an alkyl group having 1 to 10 carbon atoms, and may be the same or different from each other; and n is an integer of 4 to 20.

5. The electrolyte composition according to claim 1, wherein the electrolyte composition is formed of said nanoparticles or said porous inorganic film chemically modified by said ammonium group or said nitrogen-containing heterocyclic group through the intermediary of an acyclic hydrocarbon group straight chain having a functional group at one end thereof.

6. A dye-sensitized solar cell which comprises:
a semiconductor electrode with a dye adsorbed on the surface thereof;
a counter electrode disposed so as to face said semiconductor electrode; and
an electrolyte layer disposed between said semiconductor electrode and said counter electrode, wherein:
said electrolyte layer comprises an electrolyte composition having:
nanoparticles with an ammonium group or a nitrogen-containing heterocyclic group bound thereto; or
a porous inorganic film with an ammonium group or a nitrogen-containing heterocyclic group bound thereto.
